(19) United States
(12) Patent Application Publication
(10) Pub. No.: US 2015/0043266 A1
(43) Pub. Date: Feb. 12, 2015

(54) ENHANCED TEMPERATURE RANGE FOR RESISTIVE TYPE MEMORY CIRCUITS WITH PRE-HEAT OPERATION

(71) Applicant: Samsung Electronics Co., Ltd., Suwon-si (KR)

(72) Inventor: YongSik YOUN, Cupertino, CA (US)

(73) Assignee: Samsung Electronics Co., Ltd., Suwon-si (KR)

(21) Appl. No.: 14/092,867

(22) Filed: Nov. 27, 2013

Related U.S. Application Data
(60) Provisional application No. 61/864,504, filed on Aug. 9, 2013.

(51) Int. Cl. G11C 29/56; G11C 13/00

(52) U.S. Cl. CPC G11C 29/56; G11C 13/0021
USPC 365/148

(57) ABSTRACT

Example embodiments include devices, systems, and methods for enhancing an operating temperature range for resistive type memory devices. After powering up the resistive type memory die, the die temperature of the resistive type memory die is sensed. If the sensed die temperature is less than a predefined temperature threshold, one or more heaters proximately disposed to one or more memory cells of the resistive type memory die are enabled. The heaters are disabled responsive to the sensed die temperature being greater than a predefined temperature threshold. Memory write operations are enabled responsive to the sensed die temperature being greater than the predefined temperature threshold. After enabling the memory write operations, an enabled state of the memory write operations is maintained until the resistive type memory die is powered down. If the die temperature happens to fall below the predefined temperature threshold at a later time, additional heat is produced.

### BACKGROUND

Inventive concepts relate to resistive type memory circuits, and more particularly to memory pre-heat devices and methods for enhancing an operating temperature range of the resistive type memory circuits.

Resistive type memories encompass a new generation of non-volatile memory and are expected to become more prevalent in the marketplace. Resistive type memories can include, for example, spin transfer torque (STT) magnetoresistive random-access memory (MRAM), MRAM (of the non-STT variety), memristor RAM, ReRAM, CBRAM, and the like.

It is preferable for STT-MRAM to operate within a set temperature range. Industrial operating temperature range requirements call for memory products to operate from −40 degrees Celsius on up. For magnetic tunnel junctions (MTJ) used in STT-MRAM, the switching voltage is inversely proportional to temperature. That is, lower temperature needs higher switching voltage. MTJ write issues exist at low temperature due to the higher required switching voltage. These problems include poor reliability due to increased possibility of breakdown and large power consumption due to high VDD supply.

FIGS. 1A and 1B are schematic diagrams of an example STT MRAM memory cell 30. In some embodiments, the memory cell 30 is a spin transfer torque (STT) magnetoresistive random-access memory (MRAM) memory cell. It will be understood, however, that inventive concepts described herein apply to resistive memories of other types, such as MRAM (of the non-STT variety), memristor RAM, ReRAM, CBRAM, and the like.

FIG. 1A shows a magnetic tunnel junction (MTJ) 10, which forms a variable resistor in an STT-MRAM type memory cell, and an associated select transistor 20, together forming an STT-MRAM cell 30. The MTJ 10 includes a reference or pinned layer 12, a free layer 16, and a tunneling layer 14 disposed between the reference layer 12 and the free layer 16. Transistor 20 is often an NMOS type transistor due to its inherently higher current drive, lower threshold voltage, and smaller area relative to a PMOS type transistor.

In the following description, an MRAM cell is defined as being in a logic “0” state when the free and reference layers of its associated MTJ are in a parallel (P) state, i.e., the MTJ exhibits a low resistance. Conversely, an MRAM cell is defined as being in a logic “1” state when the free and reference layers of its associated MTJ are in an anti-parallel (AP) state, i.e., the MTJ exhibits a high resistance. It will be understood that in other embodiments, the MRAM cell can be defined as being in the logic “0” state when in an AP state, and the logic “1” state when in a P state. Furthermore, in the following, it is assumed that the reference layer of the MTJ 10 faces its associated select transistor, as shown in FIG. 1A.

Therefore, in accordance with the discussion above, a current flowing along the direction of arrow 35 (i.e., the up direction) either (i) causes a switch from the P state to the AP state thus to write a “1”, or (ii) stabilizes the previously established AP state of the associated MTJ. Likewise, a current flowing along the direction of arrow 40 (i.e., the down direction) either (i) causes a switch from the AP state to the P state thus to write a “0”, or (ii) stabilizes the previously established P state of the associated MTJ. It is understood, however, that in other embodiments this orientation may be reversed so that the free layer of the MTJ faces its associated select transistor. In such embodiments (not shown), a current flowing along the direction of arrow 35 either (i) causes a switch from the AP state to the P, or (ii) stabilizes the previously established P state of the associated MTJ Likewise, in such embodiments, a current flowing along the direction of arrow 40 either (i) causes a switch from the P state to the AP state, or (ii) stabilizes the previously established AP state.

FIG. 1B is a schematic representation of MRAM 30 of FIG. 1A in which MTJ 10 is shown as a storage element whose resistance varies depending on the data stored therein. The MTJ 10 changes its state (i) from P to AP when the current flows along arrow 35, and/or (ii) from AP to P when the current flows along arrow 40.

The voltage required to switch the MTJ 10 from an AP state to a P state, or vice versa, must exceed a critical value V_{c}. The current corresponding to this voltage is referred to as the critical or switching current I_{c}. Under a normal operating mode, to transition from the P state (i.e., low resistance state) to AP state (i.e., high resistance state), a positive write voltage of at least V_{c} is applied so that a current level of at least the switching current I_{c} flows through the memory cell. Once in the AP state, removing the applied voltage does not affect the state of the MTJ 10. Likewise, to transition from the AP state to the P state under the normal operating mode, a negative write voltage of −V_{c} or lower is applied so that a current level of at least the switching current I_{c} flows through the memory cell in the opposite direction. Once in the P state, removing the applied voltage does not affect the state of the MTJ 10.

In other words, MTJ 10 can be switched from an anti-parallel state (i.e., high resistance state, or logic “1” state) to a parallel state so as to store a “0” (i.e., low resistance state, or logic “0” state). Assuming that MTJ 10 is initially in a logic “1” or AP state, to store a “0”, under the normal operating mode, a write current at least as great or greater than the critical current I_{c} is caused to flow through transistor 20 in the direction of arrow 40. To achieve this, the source node (SL or source line) of transistor 20 is coupled to the ground potential via a resistive path (not shown), a positive voltage is applied to the gate node (WL or word line) of transistor 20, and a positive voltage is applied to the drain node (BL or bit line) of transistor 20.

The MTJ 10 can also be switched from a parallel state to an anti-parallel state so as to store a “1”. Assuming that MTJ 10 is initially in a logic “0” or P state, to store a “1”, under the normal operating mode, a write current at least as great or greater than the critical current I_{c} is caused to flow through transistor 20 in the direction of arrow 35. To achieve this, node SL is supplied with a positive voltage via a resistive path (not shown), node WL is supplied with a positive voltage, and node BL is coupled to the ground potential via a resistive path (not shown).

As mentioned above, MTJ write issues are manifested at low temperatures due to the higher required switching voltage. Moreover, challenges arise such as poor reliability due to the increased possibility of breakdown and large power consumption due to the high Vdd supply. These and other limitations in the prior art are addressed by embodiments of the inventive concept disclosed herein, without compromising other memory chip requirement such as a simple and small area requirement, no additional writing delay, and no extra power consumption.

### BRIEF SUMMARY

According to one embodiment of the inventive concept, a method for enhancing an operating temperature range for a resistive type memory die includes powering up the resistive type memory die, sensing a die temperature of the resistive type memory die, enabling one or more heaters proximately disposed to one or more memory cells of the resistive type memory die responsive to the sensed die temperature being less than a predefined temperature threshold, and disabling the one or more heaters responsive to the sensed die temperature being greater than a predefined temperature threshold.

The memory write operations may be enabled responsive to the sensed die temperature being greater than the predefined temperature threshold. After enabling the memory write operations, an enabled state of the memory write operations may be maintained until the resistive type memory die is powered down. In addition, after enabling the memory write operations, die temperature of the resistive type memory die may be sensed, and responsive to the sensed die temperature being less than the predefined temperature threshold, heat may be produced by enabling the one or more heaters proximately disposed to the one or more memory cells of the resistive type memory die. Responsive to the sensed die temperature being greater than the predefined temperature threshold, the one or more heaters may be disabled.

Another embodiment of the inventive concept includes a temperature control apparatus for use with a resistive type memory die. The temperature control apparatus may include one or more temperature sensors configured to sense a die temperature of the resistive type memory die, and a temperature control circuit configured to enable one or more heaters proximately disposed to one or more memory cells of the resistive type memory die responsive to the sensed die temperature being less than a predefined temperature threshold. The temperature control circuit may disable the one or more heaters responsive to the sensed die temperature being greater than a predefined temperature threshold.

Yet another embodiment of the inventive concept includes a computing system, comprising a bus, a memory device coupled to the bus, wherein the memory device includes a resistive type memory die, and a processor coupled to the bus and configured to store information in the memory device. The memory device may further comprise one or more temperature sensors configured to sense a die temperature of the resistive type memory die, and a temperature control circuit configured to enable one or more heaters proximately disposed to one or more memory cells of the resistive type memory die responsive to the sensed die temperature being less than a predefined temperature threshold. The temperature control circuit may disable the one or more heaters responsive to the sensed die temperature being greater than a predefined temperature threshold.

The foregoing and other features and advantages of the inventive concept will become more readily apparent from the following detailed description of the example embodiments, which proceeds with reference to the accompanying drawings.

### BRIEF DESCRIPTION OF THE DRAWINGS

FIGS. 1A and 1B are schematic diagrams of an example STT MRAM memory cell, according to the prior art.

FIG. 2A is a diagram illustrating the switching voltage of an example STT MRAM memory cell at high and low values of MTJ resistance.

FIG. 2B is a more detailed diagram illustrating the switching voltage of an example STT MRAM memory cell at high and low values of MTJ resistance for different temperatures.

FIG. 3 is an example block diagram of a resistive type memory cell and associated writer and regulator blocks.

FIGS. 4A and 4B are diagrams illustrating memory write issues encountered at relatively colder temperatures.

FIG. 5 illustrates a memory die having associated temperature sensors and heat generators in accordance with embodiments of the inventive concept.

FIG. 6 is a diagram illustrating operation of the heat generators in accordance with embodiments of the inventive concept.

FIGS. 7A and 7B are diagrams illustrating write voltage as a function of die temperature in accordance with embodiments of the inventive concept.

FIG. 8 is a flow diagram illustrating a technique for enhancing the operating temperature range of resistive type memories in accordance with embodiments of the inventive concept.

FIG. 9 is a waveform diagram illustrating various signals and other values for enhancing the operating temperature range of resistive type memories in accordance with embodiments of the inventive concept.

FIGS. 10A, 10B, and 10C are schematic block diagrams illustrating a sequence of events associated with enhancing the operating temperature range of resistive type memories in accordance with embodiments of the inventive concept.

FIG. 11 is a circuit diagram illustrating a temperature sensor and a temperature control circuit in accordance with embodiments of the inventive concept.

FIG. 12 is a diagram illustrating hysteresis in the regulation of the die temperature in accordance with embodiments of the inventive concept.

FIGS. 13A and 13B illustrate example diagrams of heaters and associated switches in accordance with embodiments of the inventive concept.

FIG. 14 is a block diagram of a memory device, including a resistive type memory, according to an embodiment of the inventive concept.

FIG. 15 is a block diagram schematically illustrating a computing system, including a host and a resistive type memory storage device, according to an embodiment of the inventive concept.

FIG. 16 is a block diagram schematically illustrating a computing system, including a memory controller and a resistive type memory, according to an embodiment of the inventive concept.

FIG. 17 is a block diagram schematically illustrating a memory system in which a flash memory is replaced with a storage class memory using a resistive memory, according to an embodiment of the inventive concept.

FIG. 18 is a block diagram schematically illustrating a memory system in which a synchronous DRAM is replaced with a storage class memory using a resistive memory, according to an embodiment of the inventive concept.

FIG. 19 is a block diagram schematically illustrating a memory system in which a synchronous DRAM and a flash memory are replaced with a storage class memory using a resistive memory according to an embodiment of the inventive concept.

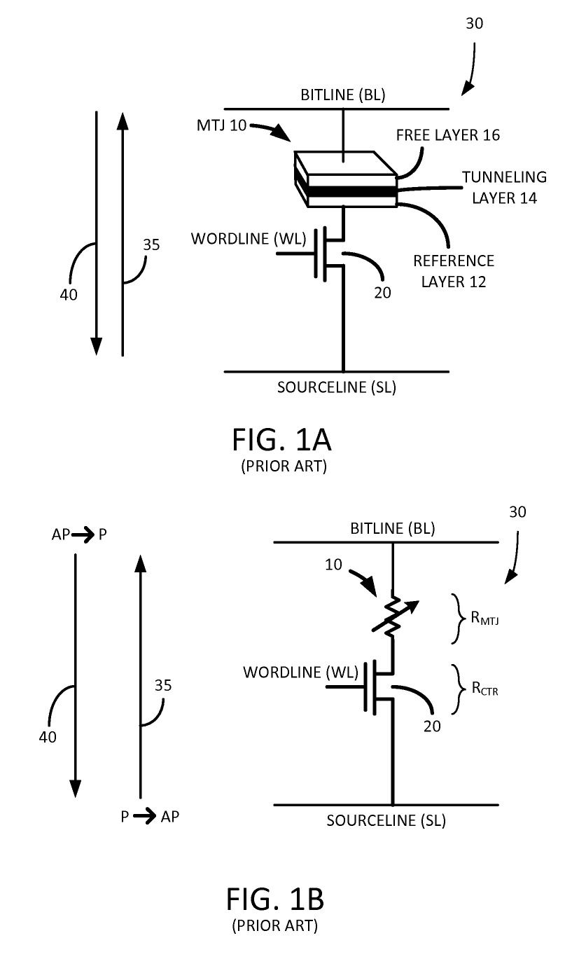

### DETAILED DESCRIPTION

Reference will now be made in detail to embodiments of the inventive concept, examples of which are illustrated in the accompanying drawings. In the following detailed description, numerous specific details are set forth to enable a thorough understanding of the inventive concept. It should be understood, however, that persons having ordinary skill in the art may practice the inventive concept without these specific details. In other instances, well-known methods, procedures, components, circuits, and networks have not been described in detail so as not to unnecessarily obscure aspects of the embodiments.

It will be understood that, although the terms first, second, etc. may be used herein to describe various elements, these elements should not be limited by these terms. These terms are only used to distinguish one element from another. For example, a first circuit could be termed a second circuit, and, similarly, a second circuit could be termed a first circuit, without departing from the scope of the inventive concept.

The terminology used in the description of the inventive concept herein is for the purpose of describing particular embodiments only and is not intended to be limiting of the inventive concept. As used in the description of the inventive concept and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The components and features of the drawings are not necessarily drawn to scale.

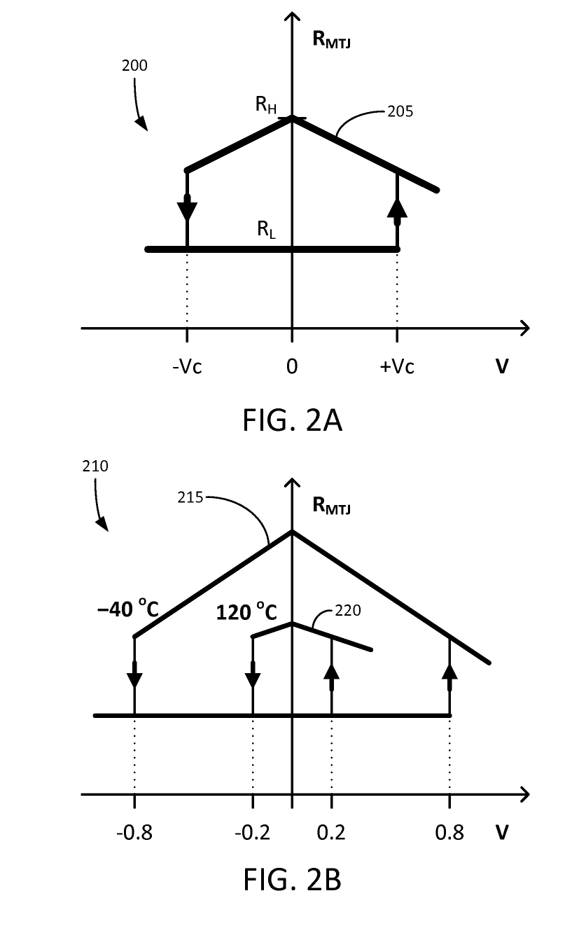

FIG. 2A is a diagram 200 illustrating the switching voltage (e.g., +V_{c} or −V_{c}) of an example STT MRAM memory cell at high (R_{H}) and low (R_{L}) values of MTJ resistance. When the MTJ is configured to have a low MTJ resistance of R_{L}, a positive write voltage of at least the switching voltage +V_{c} is needed to achieve a write error rate (WER) of about 0.5. The WER is a probability that the magnetization of the memory cell does not switch in response to an attempt to switch the memory cell. When the MTJ is configured to have a high MTJ resistance of R_{H}, a negative write voltage of the switching voltage −V_{c} or lower is needed to achieve a write error rate (WER) of about 0.5. Line 205 of the diagram 200 shows the relationship between the MTJ resistance values and the corresponding switching voltage.

FIG. 2B is a more detailed diagram 210 illustrating the switching voltage of an example STT MRAM memory cell at high and low values of MTJ resistance for different temperatures. Diagram 210 is similar to diagram 200, but as can be seen in diagram 210, two different temperatures (e.g., −40 degrees Celsius and +120 degrees Celsius) are shown. The switching voltage is affected by the die temperature.

The write voltage applied to the memory cell may be determined at least in part by the measured and/or set temperature of the die. In other words, memory write voltage may be adjusted based on sensed temperature of the die. In addition, as further described below, the temperature of the die may be controlled at least in part using one or more integrated die heaters. This, in turn, can be used to control or otherwise influence the applied memory write voltage levels.

Line 215 of the diagram 210 shows the relationship between the MTJ resistance values and the corresponding switching voltage (e.g., +0.8 Volts or −0.8 Volts) at a die temperature of −40 degrees Celsius. Line 220 of the diagram 210 shows the relationship between the MTJ resistance values and the corresponding switching voltage (e.g., +0.2 Volts or −0.2 Volts) at a die temperature of +120 degrees Celsius. When the die temperature is relatively colder (e.g., −40 degrees Celsius), the switching voltage has a wide variation relative to when the die temperature is relatively warmer (e.g., 120 degrees Celsius).

For example, in automotive applications, space applications, or other rugged applications, temperatures can drop very low, which directly affect the switching voltage, which in turn has ramifications on the operability and reliability of resistive type memories.

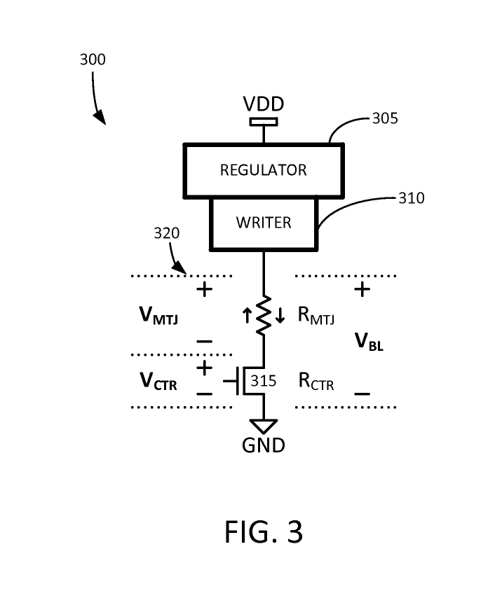

FIG. 3 is an example block diagram 300 of a resistive type memory cell 320 and an associated writer block 310 and regulator block 305. A voltage supply VDD is coupled the regulator 305 and a ground voltage GND is coupled to a cell transistor 315 of the resistive type memory cell 320. The value V_{MTJ} is the voltage drop across the resistance R_{MTJ}. The V_{MTJ} value is equal to two (2) times the switching voltage V_{c} to achieve a WER of zero (0), or nearly zero. The value V_{CTR} is the voltage drop across the cell transistor 315. To reduce memory cell area, the cell transistor resistance R_{CTR} is set substantially equivalent to the low value (i.e., R_{L}) of the MTJ resistance R_{MTJ}. The value V_{BL} is the voltage drop across both the resistance R_{MTJ} and the cell transistor resistance R_{CTR}. The value V_{BL} is referred to as the write voltage. Specifically, in this example, the value V_{BL} is equal to two (2) times the value V_{MTJ}, or thereabout. To achieve a WER of zero or near zero, in this example, the write voltage V_{BL} is four (4) times the switching voltage V_{c} (i.e., write voltage V_{BL}=2*V_{MTJ}, where V_{MTJ}=2*V_{c}).

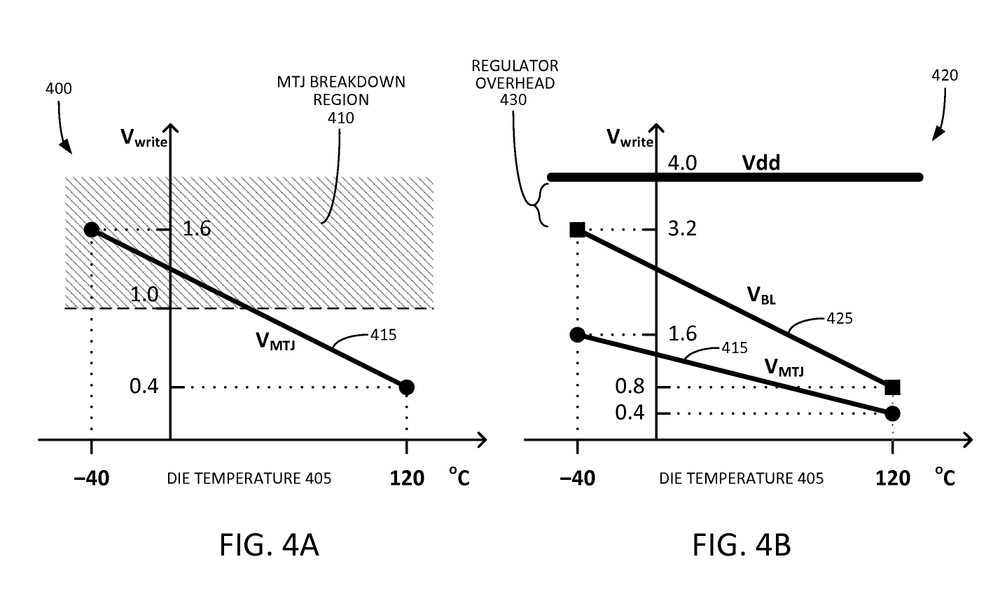

FIGS. 4A and 4B illustrate example diagrams 400 and 420, respectively, demonstrating memory write issues that are encountered at relatively colder temperatures. The values V_{MTJ} and V_{BL} are plotted as a function of die temperature 405. As can be seen in diagram 400, when the die temperature is relatively colder (e.g., −40 degrees Celsius), the V_{MTJ} value, as shown by line 415, is 1.6 Volts, which is problematic because it is within the MTJ breakdown region 410. FIG. 4B includes the additional line 425 showing the write voltage V_{BL} value as a function of the die temperature 405. When V_{MTJ} has a value of 1.6 Volts, V_{BL} has a value of 3.2 Volts. To provide sufficient regulator overhead 430, the voltage supply VDD has a value of 4.0 Volts. Operating at cold temperatures, such as −40 degrees Celsius, can cause the resistive type memory cells to consume large amounts of power, and at the same time, such operating conditions can cause reliability issues due to breakdown of the MTJ region.

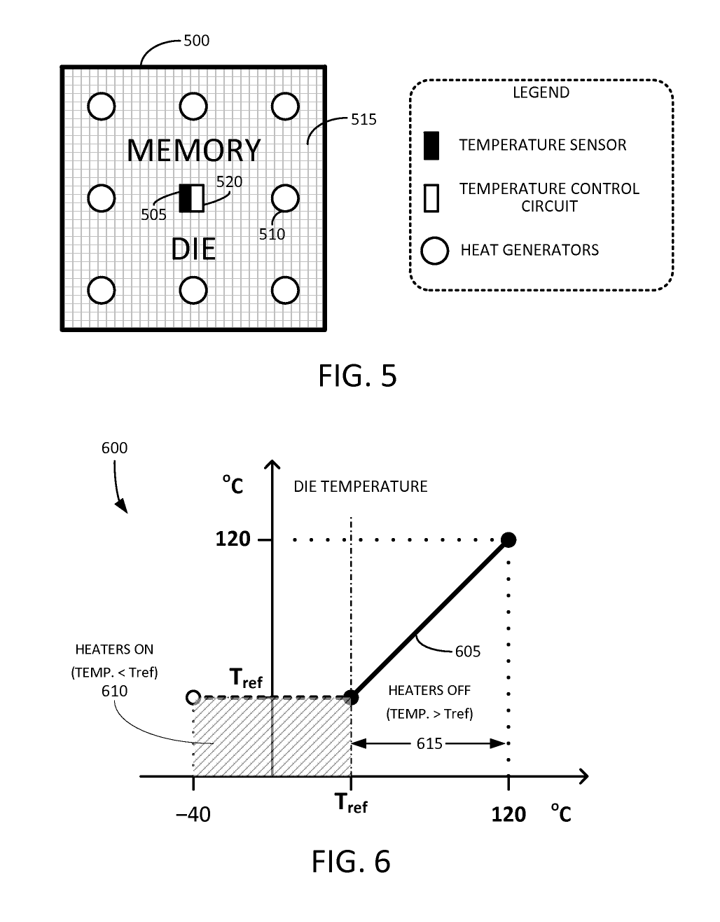

FIG. 5 illustrates a memory die 500 having associated one or more temperature sensors (e.g., 505) and one or more heat generators (e.g., 510) in accordance with embodiments of the inventive concept. FIG. 6 is a diagram 600 illustrating operation of the heat generators in accordance with embodiments of the inventive concept. The heat generators 510 are also referred to herein as heaters 510. Reference is now made to FIGS. 5 and 6.

The one or more temperature sensors (e.g., 505) can sense a die temperature 605 of the resistive type memory die 500. A temperature control circuit 520 can enable or otherwise turn on one or more heaters 510 proximately disposed to one or more memory cells 515 of the resistive type memory die 500 responsive to the sensed die temperature 605 being less than a predefined temperature threshold T_{ref}, as shown at 610. The temperature control circuit 520 can disable or otherwise turn off the one or more heaters 510 responsive to the sensed die temperature 605 being greater than a predefined temperature threshold T_{ref}, as shown at 615.

The one or more heaters 510 can generate heat during a pre-heat operation. The pre-heat operation, however, may be omitted if the die temperature is determined to be less than the predefined temperature threshold T_{ref} following power up. The one or more heaters 510 can be proximately disposed to memory cells 515 of the resistive type memory die 500, and provide heat to the memory cells 515, either during a pre-heat operation or after memory writes are enabled, or both.

A regulator circuit (e.g., 305 of FIG. 3) can enable memory write operations responsive to the sensed die temperature 605 being greater than the predefined temperature threshold T_{ref}. After enabling the memory write operations, the regulator circuit 305 can maintain an enabled state of the memory write operations until the resistive type memory die 500 is powered down. In addition, after enabling the memory write operations, the one or more temperature sensors 505 can again sense the die temperature 605 of the resistive type memory die 500. In response to the sensed die temperature 605 being less than the predefined temperature threshold T_{ref}, the temperature control circuit 520 can enable or otherwise turn on the one or more heaters 510 to produce and transfer heat to the one or more memory cells 515 of the resistive type memory die 500, as shown at 610. Moreover, after enabling the memory write operations, the temperature control circuit 520 can disable the one or more heaters 510 in response to the sensed die temperature 605 being greater than the predefined temperature threshold T_{ref}, as shown at 615. In this manner, the die temperature 605 is regulated around T_{ref} to keep the die temperature 605 above at least the predefined temperature threshold T_{ref}.

In some embodiments of the inventive concept, the one or more heaters 510 can be disposed within the resistive type memory die 500. In some embodiments, the one or more heaters 510 can be disposed underneath power lines and ground lines (not shown) of the resistive type memory die 500. In some embodiments, the heat generators are proportionally distributed in multiple places within, on, or underneath the resistive type memory die 500. In addition, the one or more temperature sensors 505 can be disposed in one or more places, and can also be proportionally distributed within, on, or underneath the resistive type memory die 500.

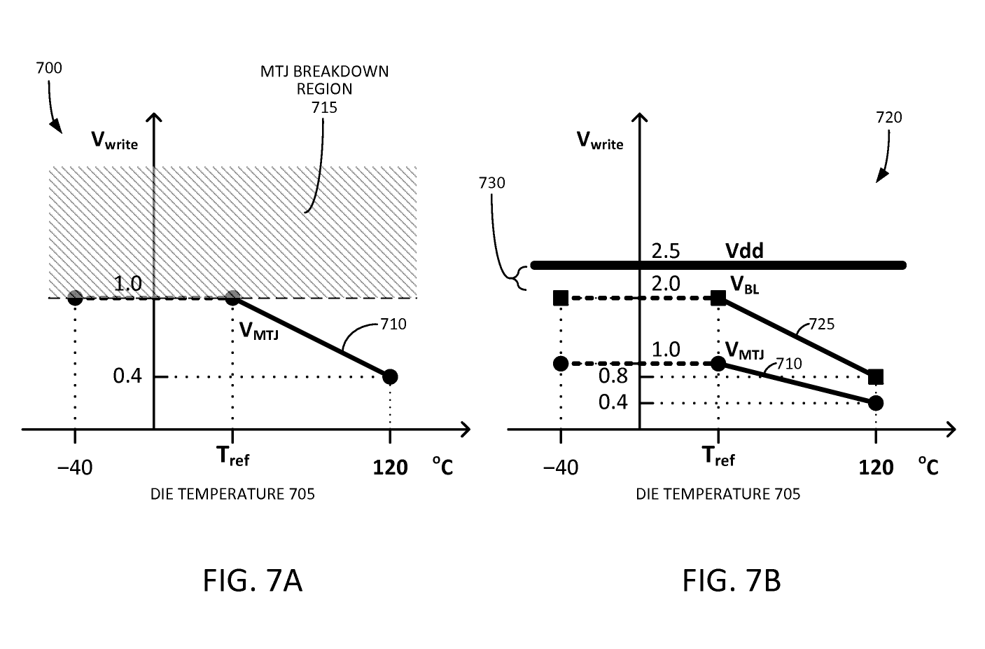

FIGS. 7A and 7B are diagrams 700 and 720, respectively, illustrating a write voltage (e.g., V_{BL}) as a function of die temperature 705 in accordance with embodiments of the inventive concept. Both of the values V_{MTJ} and V_{BL} are plotted as a function of die temperature 705. As can be seen in diagram 700, when the die temperature is relatively colder (e.g., −40 degrees Celsius), the V_{MTJ} value, as shown by line 710, is 1.0 Volt, which avoids the MTJ breakdown region 715. Because the die temperature 705 is maintained above the predefined temperature threshold T_{ref}, the V_{MTJ} value need not rise above 1 Volt. It will be understood that the value of 1 Volt for the V_{MTJ} value is illustrative, and is not limited to solely this value. The V_{MTJ} value can be made lower due to the temperature control apparatus described above with reference to FIGS. 5 and 6, particularly as transistor sizes continue to decrease with the general advance of semiconductor processing technology.

FIG. 7B includes the additional line 725 showing the write voltage V_{BL} value as a function of the die temperature 705. When V_{MTJ} has a value of 1.0 Volt, V_{BL} has a value of 2.0 Volts. To provide sufficient regulator overhead 730, the voltage supply VDD has a value of 2.5 Volts. It will be understood that the write voltage of 2.0 Volts and the voltage supply value of 2.5 Volts are illustrative, and the embodiments described herein are not limited to these values, but rather, other values can be used and still fall within the scope of the inventive concept. The resistive type memory die can therefore operate at cold temperatures, such as −40 degrees Celsius, without consuming large amounts of power, and without suffering reliability issues associated with breakdown of the MTJ region.

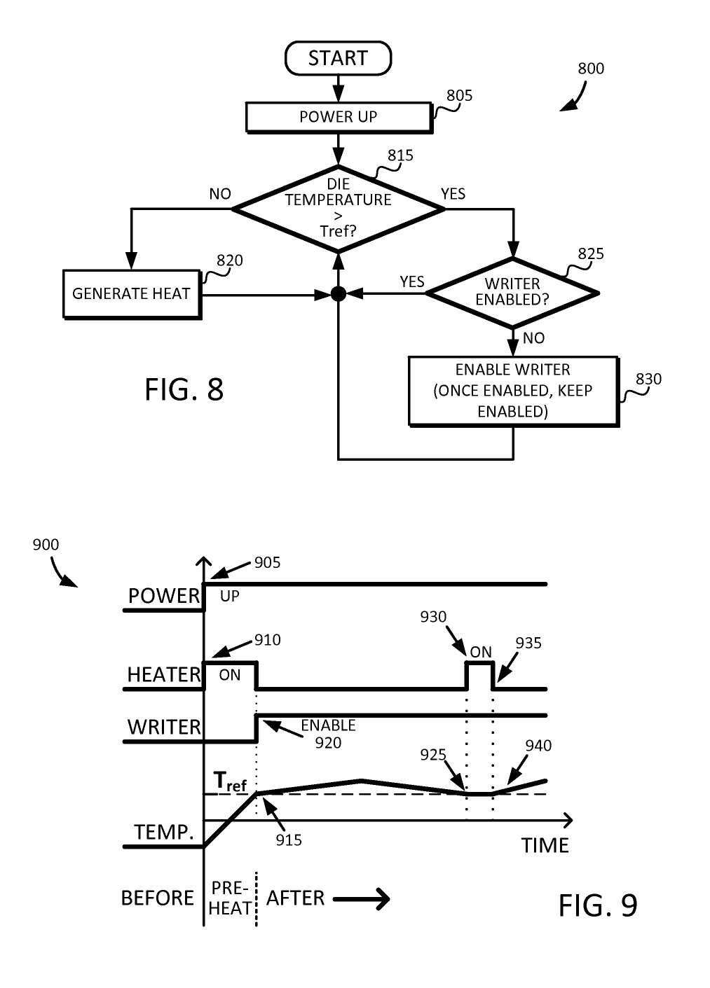

FIG. 8 is a flow diagram 800 illustrating a technique for enhancing the operating temperature range of resistive type memories in accordance with embodiments of the inventive concept. FIG. 9 is a waveform diagram 900 illustrating various signals and other values for enhancing the operating temperature range of resistive type memories in accordance with embodiments of the inventive concept. Reference is now made to FIGS. 8 and 9.

The technique begins at 805 where the resistive type memory die is powered up. In other words, initial power is supplied to the memory, as shown at 905 of the waveform diagram 900. After powering up the resistive type memory die, the die temperature is sensed, and a determination is made at 815 whether the die temperature is greater than a predefined temperature threshold T_{ref}. If the die temperature does not exceed the predefined temperature threshold T_{ref}, the flow proceeds to 820, where heat is generated by the heaters. The heat is produced as a result of heaters turning on, in response to a heater signal, as shown at 910 of the waveform diagram. The heaters may produce the heat during a pre-heat operation (i.e., before any memory writes have occurred). However, the pre-heat operation may be omitted if the die temperature is determined to be less than the predefined temperature threshold T_{ref} following power up.

The heaters can be proximately disposed to memory cells of the resistive type memory die, and provide heat to the memory cells, either during a pre-heat operation or after memory writes are enabled, or both.

Referring back to the determination made at 815, in response to the die temperature being greater than the predefined temperature threshold T_{ref}, as shown at 915 of the waveform diagram 900, the flow proceeds to 825, where another determination can be made whether write operations are enabled. In response to determining that write operations are not enabled, the flow proceeds to 830, where write operations are enabled. As shown at 920 of the waveform diagram 900, a writer enable signal can be asserted, which may enable the write operations. Once enabled, the write enable signal 920 can be maintained in an enabled state until power down of the memory die. This is possible due to the fast heat generating response provided by the embodiments disclosed herein.

Referring back to the determination at 825, if the writer is not yet enabled, the flow returns to 815 for additional determinations as to whether the die temperature exceeds the predefined temperature threshold T_{ref}.

After enabling the memory write operations, the die temperature of the resistive type memory die continues to be sensed at 815. In response to the sensed die temperature being less than (or equal to) the predefined temperature threshold, as shown at 925 of the waveform diagram 900, heat is produced at 820 by enabling the heaters. Such enabling of the heaters after enabling the memory write operations is shown at 930 of the waveform diagram 900.

After enabling the memory write operations and after enabling the one or more heaters, the die temperature of the resistive type memory die may be sensed yet again at 815. The heaters can be disabled, as shown at 935 of the waveform diagram 900, responsive to the sensed die temperature being greater than a predefined temperature threshold, as shown at 940 of the waveform diagram 900.

The heater signal shown at 910, 930, and 935 of the waveform diagram 900, for example, can cause the one or more heaters to be enabled or disabled. The heater signal is based, for example, on the sensed die temperature, as shown at 915, 925, and 940, respectively, of the waveform diagram 900. It will be understood that in some cases, a determination may be made to omit the pre-heating step. It will also be understood that in some cases, once the die temperature is higher than the predetermined threshold T_{ref}, the die temperature may be maintained above the threshold because the die itself generates heat from its operation.

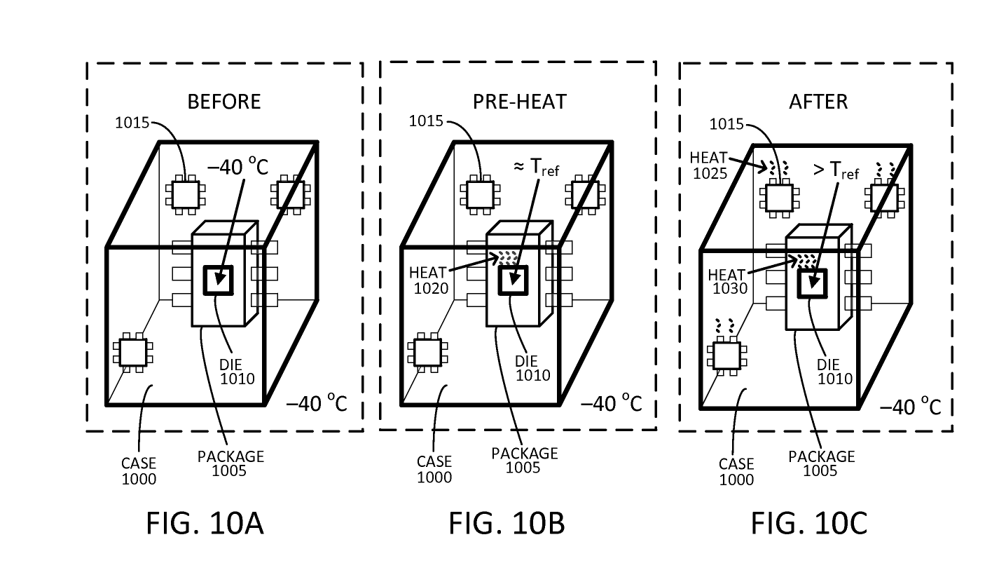

FIGS. 10A, 10B, and 10C are schematic block diagrams illustrating a sequence of events associated with enhancing the operating temperature range of resistive type memories in accordance with embodiments of the inventive concept. Reference is now made to FIGS. 10A, 10B, and 10C.

In this example, as shown in the “before” stage in FIG. 10A, the ambient temperature is negative degrees Celsius (i.e., −40° C.). The case 1000 includes a semiconductor package 1005, which itself includes the resistive type memory die 1010. Within the case 1000 are also included various other semiconductor packages or chips 1015. Because the case and its various packages and components are not yet powered up at this stage, the temperature of the die 1010 is substantially equivalent to the ambient temperature of −40° C.

As shown in FIG. 10B, during the pre-heat phase, the heaters begin producing heat 1020, thereby heating the die 1010 until the die temperature is greater than the predefined temperature threshold T_{ref}. While the ambient temperature remains at −40° C., the die temperature rapidly reaches a temperature in which memory write operations can be performed with high reliability and low power consumption. During the pre-heat phase, the die temperature is higher than the case or ambient temperature due to thermal gradient flow. As a result, an operating temperature range for the memory device is enhanced because it can operate in cold or other harsh ambient conditions.

After the pre-heat phase, the next phase is shown in FIG. 10C, in which the natural heat 1025 is produced by the other packages and chips 1015, and the natural heat 1030 is produced by the memory die 1010, generally keeping the die temperature above the predefined temperature threshold T_{ref}. However, if the die temperature happens to drop below the T_{ref} threshold, the heaters can be re-enabled, as described in detail above.

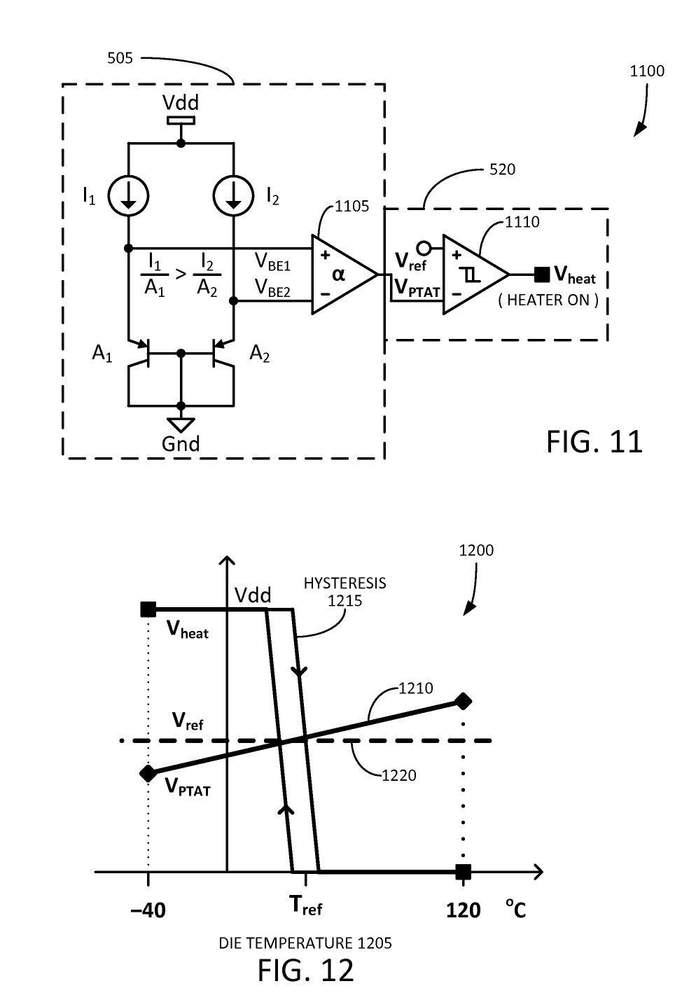

FIG. 11 is a circuit diagram 1000 illustrating the temperature sensor 505 and the temperature control circuit 520 in accordance with embodiments of the inventive concept. FIG. 12 is a diagram illustrating hysteresis in the regulation of the die temperature in accordance with embodiments of the inventive concept. Reference is now made to FIGS. 11 and 12.

The temperature sensor 505 can include a first current source I₁, a first bipolar junction transistor (BJT) A₁, a second current source I₂, and a second BJT A₂. The ratio of I₁/A₁ is greater than the ratio of I₂/A₂. The amplifier 1105 of the temperature sensor 505 can compare and amplify a voltage difference between a first base-emitter voltage V_{BE1} and a second base-emitter voltage V_{BE2}. The base-emitter voltages can be determined according to the following formula (1):

$${V}_{BE} = \frac{kT}{q} * Ln ( \frac{I}{A} ) , \qquad ( 1 )$$

where k and q are constants, and T is temperature.

The amplifier 1105 can generate a proportion to absolute temperature voltage V_{PTAT} based on the voltage difference. Specifically, V_{PTAT} can be determined according to the following formula (2):

$$\begin{matrix}{V}_{PTAT} = α * ( {V}_{BE 1} - {B}_{BE 2} ) \\ = α * \frac{kT}{q} * Ln ( \frac{{I}_{1} {A}_{2}}{{I}_{2} {A}_{1}} ) ,\end{matrix} \qquad ( 2 )$$

where α is the amplifier gain, k and q are constants, and T is temperature.

The temperature control circuit 520 can include a circuit 1110, which is configured to receive a user-configurable reference voltage value V_{ref}. Although the reference value V_{ref} is user-configurable, it need not be configured by a user, but rather, it may be set to a predefined value by default. The circuit 1110 also receives the V_{PTAT} value, compares the reference value V_{ref} to the V_{PTAT} value, and generates a heater signal Vₕₑₐₜ. The temperature control circuit 520 can transfer the heater signal Vₕₑₐₜ to the one or more heaters to enable or disable the one or more heaters.

The predefined temperature threshold T_{ref} is based on the V_{ref} value, as shown in the diagram 1200 of FIG. 12. Preferably, the T_{ref} threshold is set within the temperature range of −25° C. and +85° C. This can be achieved by setting the appropriate V_{ref} value. In other words, the predefined temperature threshold T_{ref} corresponds to substantially an intersection of the user-configurable reference value V_{ref} and the V_{PTAT} value. This generates a hysteresis effect 1215, where if the V_{PTAT} value as shown by line 1210 drops below the V_{ref} value as shown by line 1220, then the heater signal (i.e., Vₕₑₐₜ) is asserted. Conversely, if the V_{PTAT} value as shown by line 1210 rises above the V_{ref} value as shown by line 1220, then the heater signal (i.e., Vₕₑₐₜ) is not asserted. The hysteresis control loop 1215 facilitates the generation of a clear deterministic on-off heat signal Vₕₑₐₜ. The V_{ref} and the V_{PTAT} values in FIG. 12 are plotted as a function of die temperature 1205.

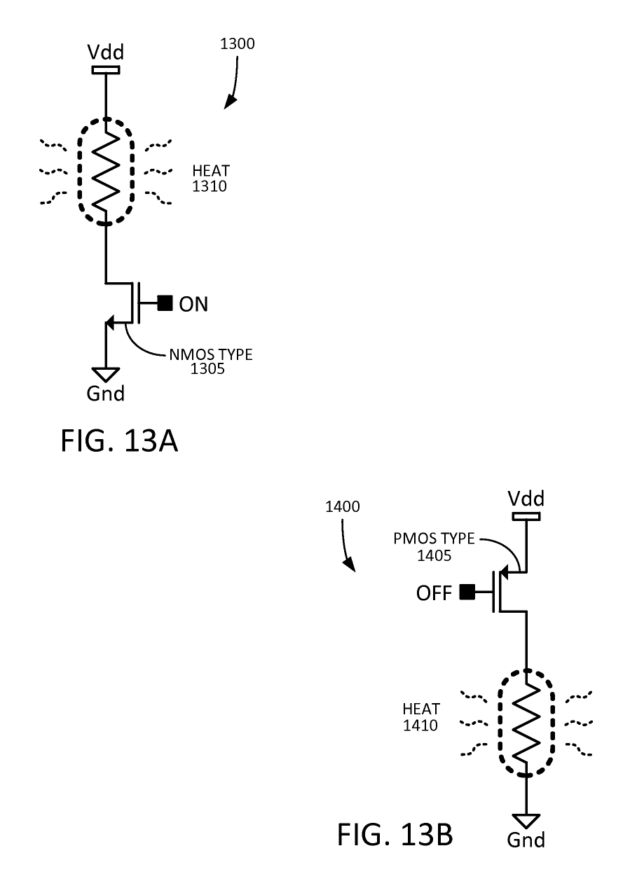

FIGS. 13A and 13B illustrate example diagrams 1300 and 1400, respectively, of heaters and associated switches in accordance with embodiments of the inventive concept. For example, the diagram 1300 includes a voltage supply VDD coupled to a heat element 1310, which itself is coupled to an NMOS type switch transistor 1305. When the NMOS type transistor receives an ON signal (i.e., a logic 1) at its gate, heat is generated by the heat element 1310. Conversely, when the NMOS type transistor receives an OFF signal (i.e., a logic 0) at its gate, the heat element 1310 does not generate heat. The diagram 1400 is similar to that of 1300 except that a PMOS type switch transistor 1405 is used. In this embodiment, heat is generated by the heat element 1410 when a logic 0 signal is received at the gate of the PMOS transistor 1405. Conversely, when the PMOS type transistor receives a logic 1 at its gate, the heat element 1410 does not generate heat.

The heat elements 1310 and 1410 can be any suitable resistive element such as metal, poly, diffusion, well, and substrate itself. In some embodiments, assuming the total current of the heat element is 200 milliamps (mA) with a 2.5 Volt VDD supply, for example, then the dissipated heat power is around 500 milliwatts (mW). As mentioned above, the heat elements can be disposed at multiple places, such as underneath the VDD and GND power lines, so that little to no die area is used.

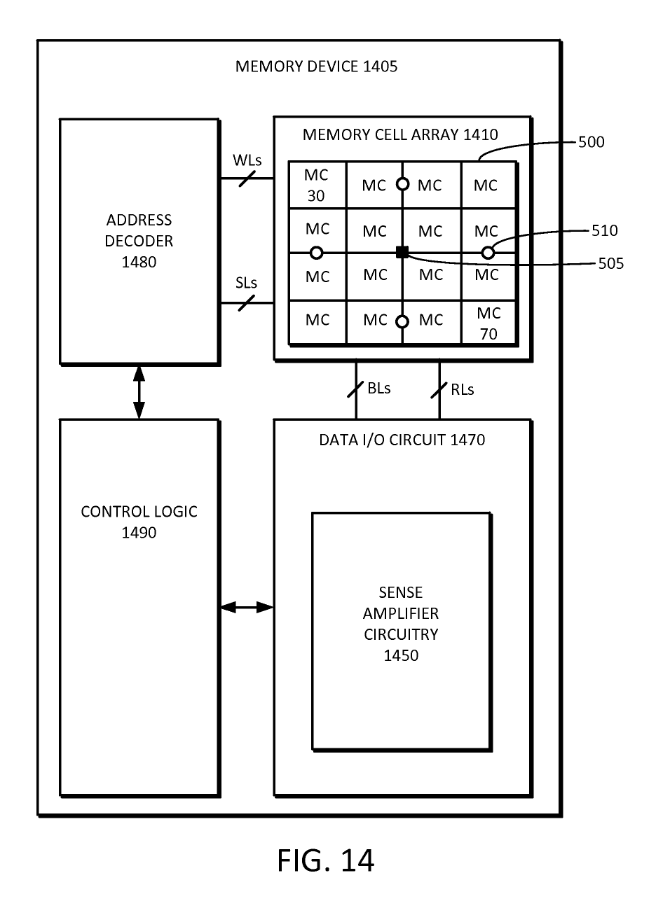

FIG. 14 is a block diagram of a memory device 1405, including a resistive type memory having temperature sensors (e.g., 505) and heaters (e.g., 510), according to an embodiment of the inventive concept. Referring to FIG. 14, the memory device 1405 includes a memory cell array 1410, a data I/O circuit 1470, an address decoder 1480, and control logic 1490. The data I/O circuit 1470 may include the sense amplifier circuitry 1450 for sensing or reading bit information stored in memory cell array 1410.

Referring to FIG. 14, the memory cell array 1410 may have a plurality of memory cells MC 30, each of which stores one or more data bits. The memory cells MC may be connected to a plurality of word lines WLs, a plurality of source lines SLs, and a plurality of bit lines BLs. The bit lines BLs may be arranged to intersect with the word lines WLs. In addition, some of the memory cells may be reference memory cells 70, as further described below. The reference memory cells 70 may be connected to a plurality of reference lines RLs.

The memory cells may be arranged at intersection portions (not shown) between the word lines and the bit lines.

The address decoder 1480 may be connected to the memory cell array 1410 via the word lines WLs and source lines SLs. The address decoder 1480 may operate responsive to the control of the control logic 1490. The address decoder 1480 may decode an input address to select the word lines WLs and source lines SLs. The address decoder 1480 may receive power (e.g., a voltage or a current) from the control logic 1490 to provide it to a selected or unselected word line.

The data input/output circuit 1470 may be connected to the memory cell array 1410 via the bit lines BLs. The data input/output circuit 1470 may operate responsive to the control of the control logic 1490. The data input/output circuit 1470 may select a bit line in response to a bit line selection signal (not shown) from the address decoder 1480. The data input/output circuit 1470 may receive power (e.g., a voltage or a current) from the control logic 1490 to provide it to a selected bit line.

The control logic 1490 may be configured to control an overall operation of the memory device 1405. The control logic 1490 may be supplied with external power and/or control signals. The control logic 1490 may generate power needed for an internal operation using the external power. The control logic 1490 may control read, write, and/or erase operations in response to the control signals.

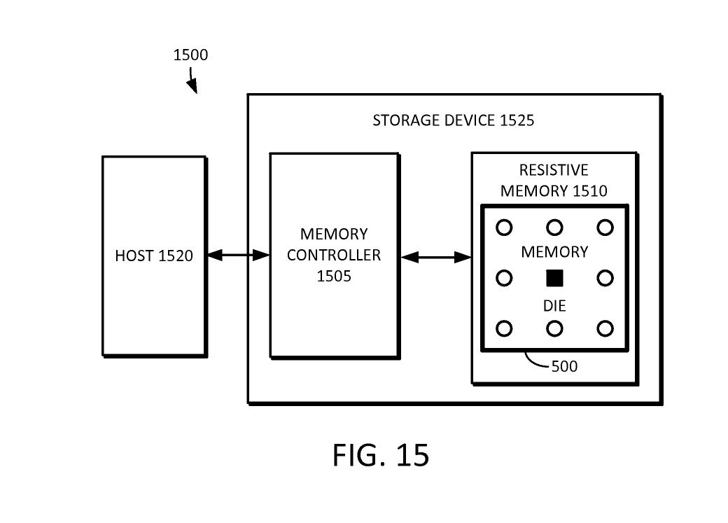

FIG. 15 is a block diagram schematically illustrating a computing system 1500, including a host 1520 and a resistive type memory storage device 1525, according to an embodiment of the inventive concept. The storage device 1525 may include a resistive type memory 1510 and a memory controller 1505. The resistive type memory 1510 may include the resistive type memory die 500, as described in detail above.

The storage device 1525 may include a storage medium such as a memory card (e.g., SD, MMC, etc.) or an attachable handheld storage device (e.g., USB memory, etc.). The storage device 1525 may be connected to the host 1520. The storage device 1525 may transmit and receive data to and from the host 1520 via a host interface. The storage device 1525 may be powered by the host 1520 to execute an internal operation.

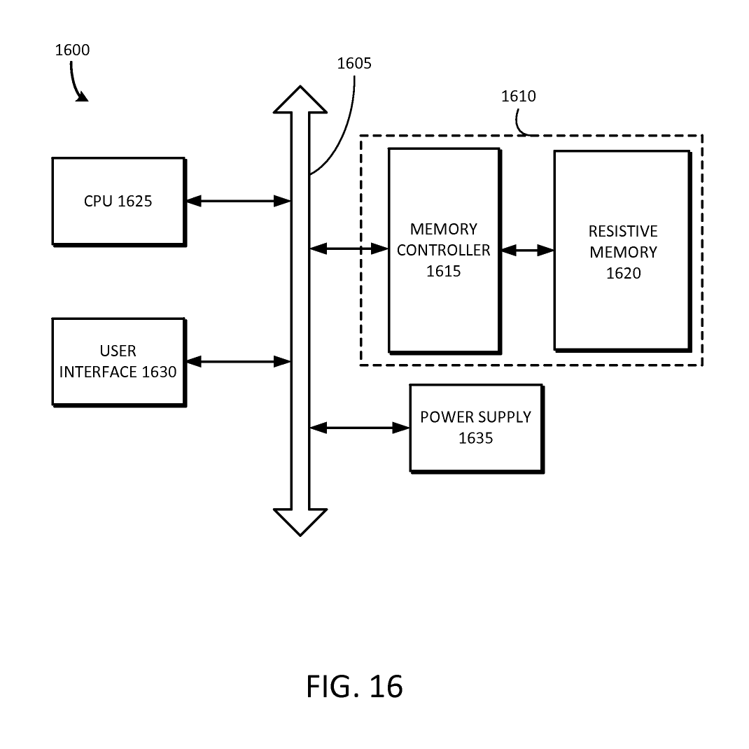

FIG. 16 is a block diagram of a computing system 1600, including a resistive memory system 1610, according to an embodiment of the inventive concept. Referring to FIG. 16, the computing system 1600 includes a memory system 1610, a power supply 1635, a central processing unit (CPU) 1625, and a user interface 1630. The memory system 1610 includes a resistive memory device 1620 and a memory controller 1615. The CPU 1625 is electrically connected to a system bus 1605.

The resistive memory device 1620 may include the resistive type memory die, including temperature sensors and heaters, in accordance with an embodiment of the inventive concept. The resistive memory device 1620 may store data through the memory controller 1615. The data may be received from the user interface 1630 and/or processed by the CPU 1625. The memory system 1600 may be used as a semiconductor disc device (SSD).

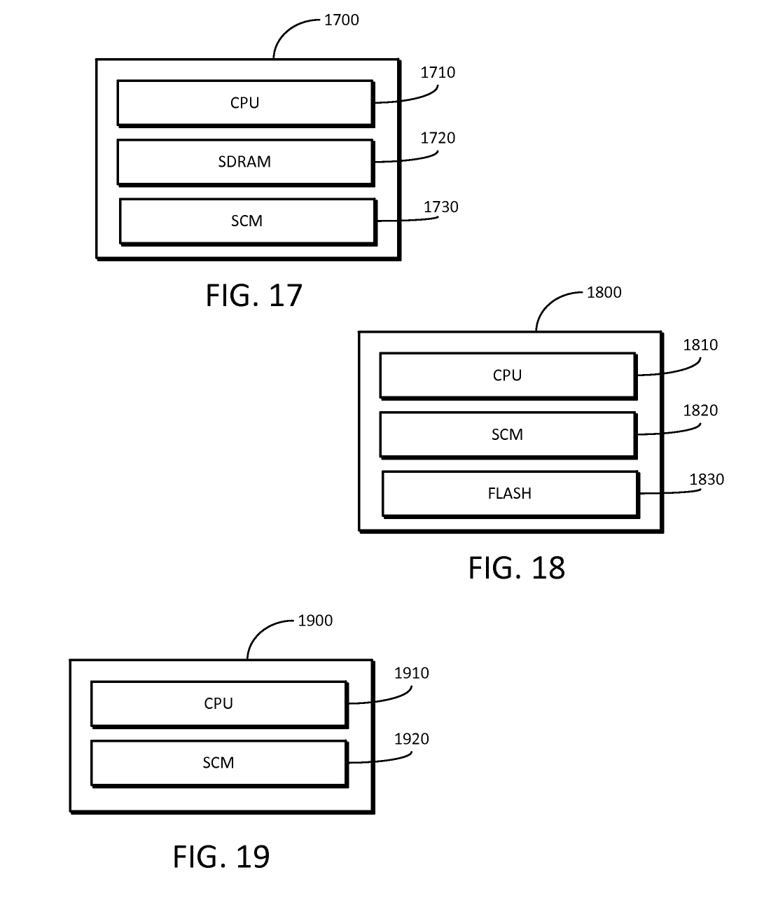

FIG. 17 is a block diagram schematically illustrating a memory system in which a flash memory is replaced with a storage class memory using a resistive memory, according to an embodiment of the inventive concept. Referring to FIG. 17, a memory system 1700 may include a CPU 1710, a synchronous DRAM (SDRAM) 1720, and a storage class memory (SCM) 1730. The SCM 1730 may be a resistive memory that is used as a data storage memory instead of a flash memory.

The SCM 1730 may access data in higher speed compared with a flash memory. For example, in a PC in which the CPU 1710 operates at a frequency of 4 GHz, a resistive memory being a type of SCM 1730 may provide an access speed higher than a flash memory. Thus, the memory system 1700 including the SCM 1730 may provide a relatively higher access speed than a memory system including a flash memory.

FIG. 18 is a block diagram schematically illustrating a memory system in which a synchronous DRAM is replaced with a storage class memory using a resistive memory, according to an embodiment of the inventive concept. Referring to FIG. 18, a memory system 1800 may include a CPU 1810, a storage class memory (SCM) 1820, and a flash memory 1830. The SCM 1820 may be used as a main memory instead of a synchronous DRAM (SDRAM).

Power consumed by the SCM 1820 may be less than that consumed by the SDRAM. A main memory may take about 40% of a power consumed by a computing system. For this reason, a technique of reducing power consumption of a main memory has been developed. Compared with the DRAM, the SCM 1820 may on average reduce 53% of dynamic energy consumption and about 73% of energy consumption due to power leak. Thus, the memory system 1800 including the SCM 1820 may reduce power consumption compared with a memory system including an SDRAM.

FIG. 19 is a block diagram schematically illustrating a memory system in which a synchronous DRAM and a flash memory are replaced with a storage class memory using a resistive memory according to an embodiment of the inventive concept. Referring to FIG. 19, a memory system 1900 may include a CPU 1910 and a storage class memory (SCM) 1920. The SCM 1920 may be used as a main memory instead of a synchronous DRAM (SDRAM) and as a data storage memory instead of a flash memory. The memory system 1900 may be advantageous in the light of data access speed, low power, cost, and use of space.

A resistive memory device according to the inventive concept may be packed by at least one selected from various types of packages such as PoP (Package on Package), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), and the like.

A resistive memory device according to an embodiment of the inventive concept may be applied to various products. The resistive memory device according to an embodiment of the inventive concept may be applied to storage devices such as a memory card, a USB memory, a solid state drive (SSD), and the like, as well as to electronic devices such as a personal computer, a digital camera, a camcorder, a cellular phone, an MP3 player, a PMP, a PSP, a PDA, and the like.

Referring to the figures described above, in some embodiments, the source lines SLs are tied to a ground GND potential, and this is the configuration that is assumed for the circuit diagram illustrated in these figures. It will be understood, however, that in some embodiments, the source lines SLs can be tied to a power supply potential VDD, and the regular VDD potential can be tied to the ground GND potential. In such case, each PMOS type transistor is replaced with an NMOS type transistor, and each NMOS type transistor is replaced with a PMOS type transistor.

The example embodiments disclosed herein provide a resistive type memory with enhanced operating temperature range. This is achieved using a simple and small die area, and including a heat element and a switch transistor. Reliability is improved and breakdown is prevented at low temperatures. Lower voltage supplies can be used, thereby resulting in reduced power loss. Once the chip is operating normally above the temperature threshold T_{ref} after power up, the heat generation response is much faster than the temperature drop speed. There is no additional writing delay because the writer is not disabled after the write enable signal has been asserted.

Moreover, the heat generated by the chip and surrounding components generally keeps the die temperature above the threshold after the pre-heat phase, and therefore, generally no extra power is needed to heat the die because the heaters can be left off. Nevertheless, if the die temperature happens to fall below the temperature threshold at any time, the heaters can be re-enabled to ensure efficient and reliable operation of the resistive type memory cells.

The above embodiments of the inventive concept are illustrative and not limitative. Various alternatives and equivalents are possible. The embodiments of the inventive concept are not limited by the type or the number of the magnetic random access memory cells included in a memory array. The embodiments of the inventive concept are not limited by the type of transistor, PMOS, NMOS or otherwise, included to operate the sense amplifier circuit, select a magnetic tunnel junction device, or the like. The embodiments of the inventive concept are not limited by the type of logic gates, NOR or NAND included to implement logical column selection or to produce control logic for the sense amplifier circuit. The embodiments of the inventive concept are not limited by the type of integrated circuit in which the inventive concept may be disposed. Nor are the embodiments of the inventive concept limited to any specific type of process technology, e.g., CMOS, Bipolar, or BICMOS that may be included to manufacture a memory. The embodiments described herein have been directed to sense amplifier circuits but are not limited thereto. The embodiments described herein may be included wherever improving response times, noise immunity characteristics, low voltage operation capabilities, larger voltage headroom features, or fewer sense errors, or the like, may be found useful.

Other similar or non-similar modifications can be made without deviating from the intended scope of the inventive concept. Accordingly, the inventive concept is not limited except as by the appended claims.

What is claimed is:

1. A method for enhancing an operating temperature range for a resistive type memory die, the method comprising:
powering up the resistive type memory die;
sensing a die temperature of the resistive type memory die;
enabling one or more heaters proximately disposed to one or more memory cells of the resistive type memory die responsive to the sensed die temperature being less than a predefined temperature threshold; and
disabling the one or more heaters responsive to the sensed die temperature being greater than a predefined temperature threshold.

2. The method of claim 1, further comprising:
enabling memory write operations responsive to the sensed die temperature being greater than the predefined temperature threshold.

3. The method of claim 2, further comprising:
after enabling the memory write operations, maintaining an enabled state of the memory write operations until the resistive type memory die is powered down.

4. The method of claim 2, further comprising:
after enabling the memory write operations, sensing the die temperature of the resistive type memory die; and
responsive to the sensed die temperature being less than the predefined temperature threshold, producing heat by enabling the one or more heaters proximately disposed to the one or more memory cells of the resistive type memory die.

5. The method of claim 4, further comprising:
after enabling the memory write operations and after enabling the one or more heaters, sensing the die temperature of the resistive type memory die; and
responsive to the sensed die temperature being greater than the predefined temperature threshold, disabling the one or more heaters.

6. The method of claim 1, wherein sensing the die temperature further includes comparing a voltage difference between a first base-emitter voltage and a second base-emitter voltage, the method further comprising:
amplifying the voltage difference;
generating a proportion to absolute temperature voltage based on the voltage difference;
receiving a user-configurable reference value;
comparing the user-configurable reference value to the proportion to absolute temperature voltage; and
generating a heater signal responsive to the comparing.

7. The method of claim 6, wherein
enabling one or more heaters includes enabling the one or more heaters responsive to the heater signal; and
disabling one or more heaters includes disabling the one or more heaters responsive to the heater signal.

8. The method of claim 6, wherein the user-configurable reference value comprises a user-configurable reference voltage.

9. The method of claim 8, further comprising:
setting the predefined temperature threshold at substantially an intersection of the user-configurable reference value and the proportion to absolute temperature voltage.

10. The method of claim 9, wherein setting the predefined temperature threshold further includes setting the predefined temperature threshold between negative 25 degrees Celsius and positive 40 degrees Celsius.

11. The method of claim 1, further comprising:
adjusting a write voltage level based on the sensed die temperature of the resistive type memory die.

12. A temperature control apparatus for use with a resistive type memory die, the apparatus comprising:
one or more temperature sensors configured to sense a die temperature of the resistive type memory die; and
a temperature control circuit configured to enable one or more heaters proximately disposed to one or more memory cells of the resistive type memory die responsive to the sensed die temperature being less than a predefined temperature threshold,
wherein the temperature control circuit is configured to disable the one or more heaters responsive to the sensed die temperature being greater than a predefined temperature threshold.

13. The temperature control apparatus of claim 12, further comprising:
a regulator circuit configured to enable memory write operations responsive to the sensed die temperature being greater than the predefined temperature threshold.

14. The temperature control apparatus of claim 13, wherein after enabling the memory write operations, the regulator circuit is configured to maintain an enabled state of the memory write operations until the resistive type memory die is powered down.

15. The temperature control apparatus of claim 13, wherein:
after enabling the memory write operations, the one or more temperature sensors are configured to sense the die temperature of the resistive type memory die; and
responsive to the sensed die temperature being less than the predefined temperature threshold, the temperature control circuit is configured to enable the one or more heaters to produce and transfer heat to the one or more memory cells of the resistive type memory die.

16. The temperature control apparatus of claim 15, wherein:
responsive to the sensed die temperature being greater than the predefined temperature threshold, the temperature control circuit is configured to disable the one or more heaters.

17. The temperature control apparatus of claim 12, wherein:
the one or more temperature sensors are each configured to compare a voltage difference between a first base-emitter voltage and a second base-emitter voltage, to amplify the voltage difference, and to generate a proportion to absolute temperature voltage based on the voltage difference; and
the temperature control circuit is configured to receive a user-configurable reference value, to compare the user-configurable reference value to the proportion to absolute temperature voltage, and to generate a heater signal responsive to the comparing.

18. The temperature control apparatus of claim 17, wherein:
the temperature control circuit is configured to transmit the heater signal to the one or more heaters to enable or disable the one or more heaters.

19. The temperature control apparatus of claim 17, wherein the user-configurable reference value comprises a user-configurable reference voltage.

20. The temperature control apparatus of claim 19, wherein:
the predefined temperature threshold corresponds to substantially an intersection of the user-configurable reference value and the proportion to absolute temperature voltage.

21. The temperature control apparatus of claim 12, wherein the one or more heaters are disposed within the resistive type memory die.

22. The temperature control apparatus of claim 12, wherein the one or more heaters are disposed underneath power lines and ground lines of the resistive type memory die.

23. A computing system, comprising:
a bus;
a memory device coupled to the bus, wherein the memory device includes a resistive type memory die; and
a processor coupled to the bus and configured to store information in the memory device;
wherein the memory device further comprises:
one or more temperature sensors configured to sense a die temperature of the resistive type memory die; and
a temperature control circuit configured to enable one or more heaters proximately disposed to one or more memory cells of the resistive type memory die responsive to the sensed die temperature being less than a predefined temperature threshold,
wherein the temperature control circuit is configured to disable the one or more heaters responsive to the sensed die temperature being greater than a predefined temperature threshold.

24. The system of claim 23, wherein the memory device further comprises:
a regulator circuit configured to enable memory write operations responsive to the sensed die temperature being greater than the predefined temperature threshold.

25. The system of claim 24, wherein after enabling the memory write operations, the regulator circuit is configured to maintain an enabled state of the memory write operations until the resistive type memory die is powered down.

26. The system of claim 24, wherein:
after enabling the memory write operations, the one or more temperature sensors are configured to sense the die temperature of the resistive type memory die; and
responsive to the sensed die temperature being less than the predefined temperature threshold, the temperature control circuit is configured to enable the one or more heaters to produce and transfer heat to the one or more memory cells of the resistive type memory die.

27. The temperature control apparatus of claim 26, wherein:
responsive to the sensed die temperature being greater than the predefined temperature threshold, the temperature control circuit is configured to disable the one or more heaters.
